(19) United States
(12) Patent Application Publication
(10) Pub. No.: US 2021/0083389 A1
(43) Pub. Date: Mar. 18, 2021

(54) ELECTRONIC PACKAGE AND METHOD FOR MANUFACTURING THE SAME

(71) Applicant: SILICONWARE PRECISION INDUSTRIES CO., LTD., Taichung (TW)

(72) Inventors: Cheng-Piao Tung, Taichung (TW); Wen-Jung Tsai, Taichung (TW)

(73) Assignee: SILICONWARE PRECISION INDUSTRIES CO., LTD., Taichung (TW)

(21) Appl. No.: 16/997,096

(22) Filed: Aug. 19, 2020

(30) Foreign Application Priority Data
Sep. 16, 2019 (TW) 108133225

(51) Int. Cl. H01Q 9/04; H01Q 1/38

(52) U.S. Cl. CPC H01Q 9/0414; H01Q 1/38

(57) ABSTRACT

An electronic package and a method for manufacturing the same are provided, where at least one substrate structure having a second antenna portion is disposed on a carrier structure having a first antenna portion, and then an antenna structure having a first antenna body and a second antenna body is stacked on the carrier structure by a plurality of supporting members to cover the first antenna portion and the second antenna portion, so that the first antenna body corresponds to the first antenna portion, and the second antenna body corresponds to the second antenna portion. The substrate structure is disposed on the carrier structure to generate 5G millimeter waves of different frequencies, such that the antenna structure can generate different antenna signals based on needs.

### BACKGROUND

### 1. Technical Field

The present disclosure relates to an electronic package, and more particularly, to an electronic package with an antenna structure and a method for manufacturing the same.

### 2. Description of Related Art

Wireless communication technology has now been widely applied to a myriad of consumer electronic products (e.g., mobile phones, tablets, and the like) for receiving and transmitting various kinds of wireless signals. To satisfy the demands for portability and ease of Internet access (for example, watching multimedia content) for consumers electronic products, wireless communication modules are designed and manufactured with lightweight and compact sizes in mind. Among them, patch antennae have been widely adopted in the wireless communication modules of electronic products due to their characteristics such as small volume, light weight and ease to manufacture.

With the improvements in image quality, multimedia content nowadays tends to have very large sizes and requires larger wireless transmission bandwidths. This has brought about the advent of fifth generation (5G) wireless transmission technology. Furthermore, as the 5G has higher transmission frequencies, the requirements for the associated wireless transmission modules are more stringent.

In regards to the future commercialization trends of the 5G technology, the application frequency range of the 5G technology is in the high-frequency band between 1 GHz and 1000 GHz, and it has a business application model that combines 5G and 4G LTE using cellular base stations built outdoor and mini base stations provided indoor. Thus, 5G mobile communication requires the use of a large amount of antennae in a base station to realize the large capacity, fast transmission and low latency of the 5G network.

FIG. 1 is a schematic perspective view of a conventional wireless communication module 1. As shown in FIG. 1, the wireless communication module 1 includes a substrate 10, a plurality of electronic components 11 disposed on the substrate 10, an antenna structure 12 and an encapsulating material 13. The substrate 10 is a circuit board with a rectangular shape. The electronic components 11 are disposed on the substrate 10 and electrically connected to the substrate 10. The antenna structure 12 is planar with an antenna body 120 and a wire 121. The antenna body 120 is electrically connected to an electronic component 11 via the wire 121. The electronic components 11 and a portion of the wire 121 are covered by the encapsulating material 13.

Taking the applications in smart phones as an example, the 5G frequency bands may include 3.5 GHz to 6 GHz, 28 GHz, 39 GHz, 60 GHz, 71 GHz to 73 GHz. Moreover, a 5G system requires the provision of more antennae to improve the signal quality and transmission speed.

However, in the conventional wireless communication module 1, the antenna structure 12 is planar, and the dimensions of the substrate 10 are fixed, so there is only a limited space (layers) available for routing. This restricts the functionality of the antenna structure 12. As a result, the wireless communication module 1 cannot provide the electrical functions required for running a 5G system, and it is difficult to meet the needs of 5G antenna operation.

Moreover, if more layout areas are added onto the surface of the substrate 10 in order to form antenna bodies 120 for a plurality of frequencies, it will inevitably increase the width of the substrate 10 and making it difficult to reduce the width of the wireless communication module 1. As a result, the wireless communication module 1 cannot meet the requirements for miniaturization.

Therefore, there is a need for a solution that addresses the aforementioned issues in the prior art.

### SUMMARY

In view of the aforementioned shortcomings of the prior art, the present disclosure provides an electronic package, which includes: a carrier structure including a first antenna portion; at least one substrate structure disposed on the carrier structure and including a second antenna portion; and an antenna structure stacked on the carrier structure via a plurality of support members to cover the first antenna portion and the second antenna portion, wherein the antenna structure includes a first antenna body corresponding to the first antenna portion and a second antenna body corresponding to the second antenna portion.

The present disclosure further provides a method for manufacturing an electronic package, which includes: providing at least one substrate structure including a second antenna portion on a carrier structure including a first antenna portion; and stacking an antenna structure on the carrier structure via a plurality of support members to cover the first antenna portion and the second antenna portion, wherein the antenna structure includes a first antenna body corresponding to the first antenna portion and a second antenna body corresponding to the second antenna portion.

In the electronic package and the method for manufacturing the same above, a first air gap is formed between the antenna structure and the carrier structure. For example, a signal frequency between the first antenna body and the first antenna portion corresponds to a height of the first air gap. Alternatively, the first air gap is located between the first antenna portion and the first antenna body. Alternatively, a second air gap is formed between the antenna structure and the substrate structure, and a height of the second air gap is less than a height of the first air gap, such that a signal frequency between the second antenna body and the second antenna portion is greater than a signal frequency between the first antenna body and the first antenna portion.

In the electronic package and the method for manufacturing the same above, an air gap is formed between the antenna structure and the substrate structure. For example, a signal frequency between the second antenna body and the second antenna portion corresponds to a height of the air gap. Alternatively, the air gap is located between the second antenna portion and the second antenna body.

In the electronic package and the method for manufacturing the same above, a plurality of the substrate structures are disposed on the carrier structure. For example, a plurality of air gaps are formed between the antenna structure and each of the substrate structures. Furthermore, heights of the plurality of air gaps are different from one another, and one of the plurality of air gaps with the smallest height has a corresponding signal frequency between the second antenna body and the second antenna portion that is the highest.

In the electronic package and the method for manufacturing the same above, an electronic component is further arranged on the carrier structure.

As can be understood from the above, in the electronic package and the method of manufacturing the same in accordance with the present disclosure, by providing the at least one substrate structure including the second antenna portion on the carrier structure including the first antenna portion to produce 5G millimeter wave (mmWave) of different frequencies, the antenna structure disposed on the carrier structure can produce different antenna signals depending on the needs, allowing the electronic component to transmit and receive 5G mmWave of the required frequencies. Thus, compared to the prior art, the electronic package of the present disclosure improves the functionality of the antenna structure, allowing the electronic package to provide the electrical functions required by the 5G system, and thus meeting the requirements of antenna operations of the 5G system.

Furthermore, the substrate structure is disposed on the carrier structure, so there is no need to add more layout areas on the carrier structure. This allows the manufacturing method of the present disclosure to produce antennae of various frequencies under predetermined sizes of the carrier structures, and allows the electronic package to meet the requirements of miniaturization.

### BRIEF DESCRIPTION OF THE DRAWINGS

FIG. 1 is a schematic cross-sectional view of a conventional wireless communication module.

FIGS. 2A and 2B are schematic cross-sectional views illustrating a method for manufacturing an electronic package in accordance with an embodiment of the present disclosure.

FIGS. 3 and 4 are schematic cross-sectional views illustrating electronic packages in accordance with other embodiments of the present disclosure.

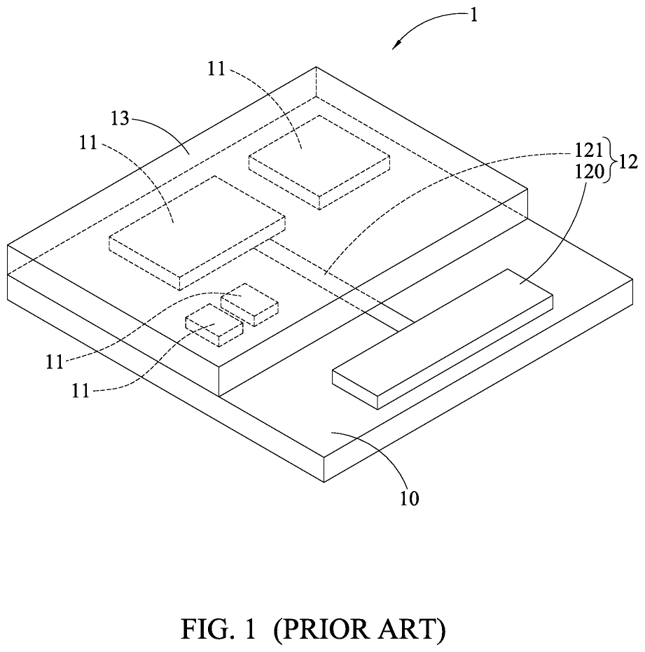

### DETAILED DESCRIPTION

The implementations of present disclosure are illustrated using the following embodiments. One of ordinary skill in the art can readily appreciate other advantages and technical effects of the present disclosure upon reading the disclosure of this specification.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and the objectives achieved by the present disclosure, any modifications, changes or adjustments to the structures, ratio relationships or sizes, are to be construed as falling within the scope covered by the technical contents disclosed herein. Meanwhile, terms such as “above,” “first,” “second,” “a,” “an,” and the like, are for illustrative purposes, and are not meant to limit the scope in which the present disclosure can be implemented. Any variations or modifications made to their relative relationships, without changing the substantial technical content, are also to be considered as within the scope in which the present disclosure can be implemented.

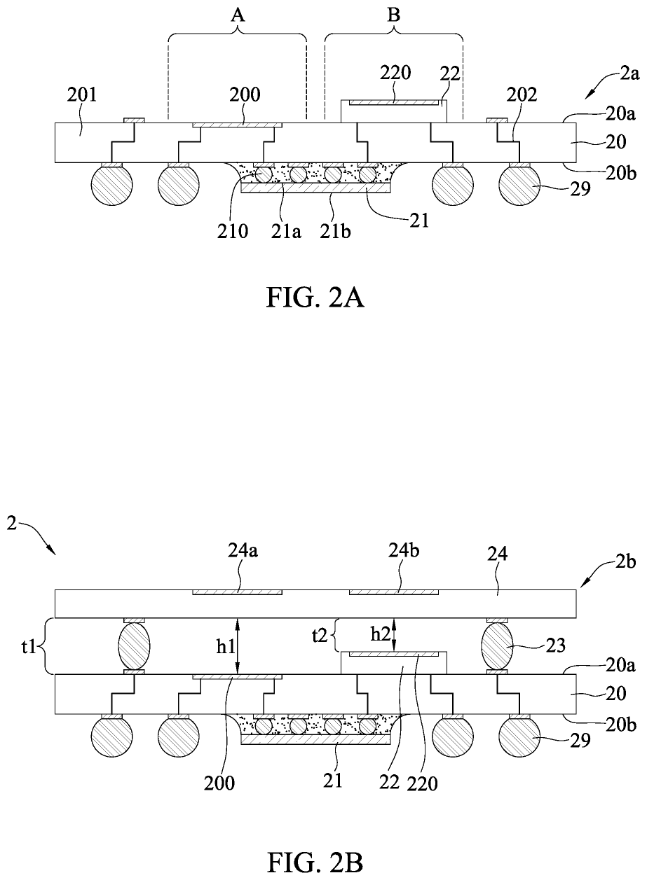

FIGS. 2A and 2B are schematic cross-sectional views illustrating a method for manufacturing an electronic package 2 in accordance with an embodiment of the present disclosure.

As shown in FIG. 2A, a carrier structure 20 equipped with an electronic component 21 is provided. An active area A and a placement area B separate from each other are defined on a surface of the carrier structure 20, wherein the active area A includes a first antenna portion 200. Then, at least one substrate structure 22 is provided on the placement area B of the carrier structure 20, thereby forming a package module 2a, wherein the substrate structure 22 includes a second antenna portion 220.

In an embodiment, the carrier structure 20 has a first side 20a and a second side 20b opposite to each other. The carrier structure 20 can be, for example, a substrate including a core layer and a circuit portion or a coreless substrate with a circuit portion. The carrier structure 20 includes an insulator 201 and a circuit layer 202 combined with the insulator 201. The circuit layer 202 can be, for example, a fan-out redistribution layer (RDL), and includes the first antenna portion 200. More specifically, the circuit layer 202 can be made of copper, for example, and the insulator 201 can be made of a dielectric material, such as polybenzoxazole (PBO), polyimide (PI), a prepreg (PP), or the like. It can be appreciated that the carrier structure can also be other carrier units for carrying electronic components (e.g., chips), such as a leadframe, a silicon interposer, etc., and the present disclosure is not limited as such.

In addition, the electronic component 21 is provided on the second side 20b of the carrier structure 20. The electronic component 21 can be an active component, a passive component or a combination of the above, wherein the active component is, for example, a semiconductor chip, and the passive component is, for example, a resistor, a capacitor or an inductor. For example, the electronic component 21 is an active component, such as a semiconductor chip capable of transmitting 5G millimeter wave (mmWave), and includes an active face 21a and a non-active face 21b opposite to each other. The electronic component 21 is provided on the circuit layer 202 in a flip-chip manner and is electrically connected with the circuit layer 202 (and the first antenna portion 200) through a plurality of conductive bumps 210 (e.g., soldering materials) provided on the active face 21a, so as to allow the first antenna portion 200 to transmit and receive the required mmWave. Alternatively, the electronic component 21 can be electrically connected with the circuit layer 202 through a plurality of bonding wires (not shown) by wire bonding. However, the ways in which the electronic component can be connected to the carrier structure are not limited to those described above.

Furthermore, the substrate structure 22 is provided on the first side 20a of the carrier structure 20 and is electrically connected to the circuit layer 202 of the carrier structure 20, such that the electronic component 21 can be electrically connected to the substrate structure 22 via the carrier structure 20. The substrate structure 22 can be, for example, a substrate including a core layer and a circuit portion or a coreless substrate with a circuit portion. The substrate structure 22 includes an insulator and a circuit layer combined to the insulator. The circuit layer can be, for example, a fan-out redistribution layer (RDL), and includes the second antenna portion 220. More specifically, the circuit layer can be made of copper, for example, and the insulator can be made of a dielectric material, such as polybenzoxazole (PBO), polyimide (PI), a prepreg (PP), or the like.

In addition, a plurality of conductive components 29 (e.g., solder balls) can be provided on the second side 20b of the carrier structure 20, such that the carrier structure 20 can be provided on a circuit board (not shown) using these conductive components 29.

As shown in FIG. 2B, an antenna structure 2b is stacked on the first side 20a of the carrier structure 20 via a plurality of support members 23, so the active area A and the substrate structure 22 are covered by the antenna structure 2b, thereby forming an electronic package 2 of the present disclosure.

In an embodiment, the antenna structure 2b is in the form of an antenna board, which includes a base 24 and a circuit portion (not shown) combined with the base 24, a first antenna body 24a and a second antenna body 24b, wherein the first antenna body 24a corresponds to the first antenna portion 200, and the second antenna body 24b corresponds to the second antenna portion 220. More specifically, the first antenna body 24a and the first antenna portion 200 transmit signals through coupling. For example, the first antenna body 24a and the first antenna portion 200 can generate radiation energy using an alternating voltage, an alternating current or radiation changes, and the radiation energy are electromagnetic fields, such that the first antenna body 24a and the first antenna portion 200 can be electromagnetically coupled to each other and antenna signals can be delivered between the first antenna body 24a and the first antenna portion 200. Similarly, the second antenna body 24b and the second antenna portion 220 can transmit signals through coupling.

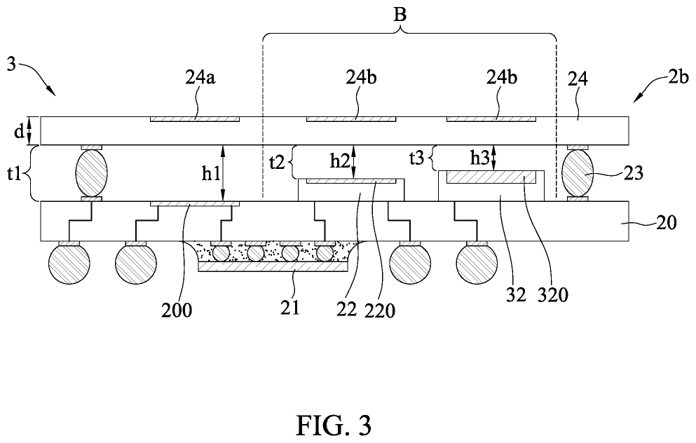

In addition, a first air gap t1 is formed between the antenna structure 2b and the first side 20a of the carrier structure 20, and a second air gap t2 is formed between the antenna structure 2b and the substrate structure 22. More specifically, the first air gap t1 is located between the first antenna portion 200 and the first antenna body 24a, while the second air gap t2 is located between the second antenna portion 220 and the second antenna body 24b, and the height h2 of the second air gap t2 is less than the height h1 of the first air gap t1. In addition, in another embodiment, as shown in FIG. 3, the number of the substrate structure 22, 32 can be selected depending on the needs, and a plurality of second air gaps t2, t3 are formed between the antenna structure 2b and the various substrate structures 22, 32, respectively. The height h2, h3 of each of the second air gaps t2, t3 can be different.

Moreover, since air is the best low-loss medium with a dielectric constant (Dk) of 1 and a dielectric loss (Df) of zero. Thus, the performance of the antennae corresponding to the 5G communication of the electronic package 2 can be improved with the formation of the air gaps. For example, the signal frequency between the first antenna body 24a and the first antenna portion 200 corresponds to the height h1 of the first air gap t1, while the signal frequencies between the second antenna body 24b and the second antenna portions 220, 320 correspond to the heights h2, h3 of the second air gaps t2, t3, respectively. More specifically, based on the principle that the smaller the height of the air gap, the larger the corresponding antenna signal frequency, the signal frequency between the second antenna body 24b and the second antenna portion 220, 320 (e.g., 39 GHz or 60 GHz) is larger than the signal frequency between the first antenna body 24a and the first antenna portion 200 (e.g., 28 GHz), and the smaller the height h2, h3 of the plurality of second air gaps t2, t3, the higher the corresponding signal frequency between the first antenna body 24a and the second antenna portion 220, 320 (i.e., the signal frequency of 60 GHz corresponding to the second antenna portion 320>the signal frequency of 39 GHz corresponding to the second antenna portion 220).

In addition, the circuit layer 202 of the carrier structure 20 is electrically connected with the circuit portion of the antenna structure 2b through the support members 23. More specifically, the support members 23 are solder balls, copper core balls, metal components made of copper, gold, etc., (for example, in the shape of a pillar, a block or a pin) or other suitable components.

By placing substrate structures 22, 32 on the carrier structure 20 to adjust heights h2, h3 of the second air gaps t2, t3, 5G mmWave of different frequencies can thus be created. As a result, the antenna structure 2b can generate different antenna signals according to the needs (that is, the signals between the first antenna body 24a and the first antenna portion 200, the signals between the second antenna body 24b and the second antenna portion 220, or the signals between another second antenna body 34b and another second antenna portion 320), allowing the RF chip (i.e., the electronic component 21) to receive and transmit 5G mmWave of the required frequencies. More specifically, the electronic component 21 receives and transmits 5G mmWave signals at 28 GHz frequency via the first antenna portion 200; alternatively, the electronic component 21 receives and transmits 5G mmWave signals at 39 GHz frequency via the second antenna portion 220 of the substrate structure 22; or alternatively, the electronic component 21 receives and transmits 5G mmWave signals at 60 GHz frequency via the second antenna portion 320 of another substrate structure 32.

Therefore, compared to the prior art, when mass producing the electronic package 2, 3, by including antenna portions for a plurality of different frequencies (i.e., the first antenna portion 200 and the second antenna portion 220, 320) in the package module 2a of the present disclosure, antenna structures 2b having different forms of antennae (e.g., the patterns of the first antenna body 24a and the second antenna body 24b, 34b vary depending on the RF needs or the thickness d of the base 24 varies depending on the RF needs) can be simply electrically connected to package modules 2a of the same type to produce RF products for various frequencies without the need to manufacture RF chips for each of the frequencies into independent package modules (for example, at least three different production lines are required to produce three type of RF modules in the prior art). This reduces the number of production lines and thus the production cost, while increasing production speed and production capacity.

Furthermore, in the present disclosure, the substrate structure 22 is stacked on the carrier structure 20, so there is no need to add more layout areas on the carrier structure 20. This allows the manufacturing method of the present disclosure to produce antennae of various frequencies (i.e., mmWave antennae) under predetermined sizes of the carrier structures 20, and allows the electronic package 2, 3 to meet the requirements of miniaturization.

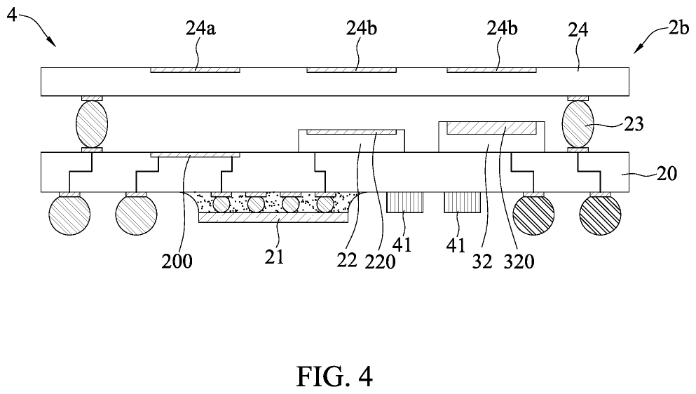

On the other hand, a single one of the electronic component 21 can transmit and receive one or a plurality of signals depending on the needs. Alternatively, a plurality of electronic components 21, 41 can be provided in an electronic package 4 shown in FIG. 4 to correspondingly control the first antenna portion 200 and the second antenna portions 220, 320.

The present disclosure further includes an electronic package 2, 3, 4, including a carrier structure 20, at least one substrate structure 22, 32 and an antenna structure 2b.

An active area A and a placement area B separate from each other are defined on a surface of the carrier structure 20, wherein the active area A includes a first antenna portion 200.

The substrate structure 22, 32 is provided on the placement area B of the carrier structure 20, wherein the substrate structure 22 includes a second antenna portion 220, 320.

The antenna structure 2b is stacked on the carrier structure 20 via a plurality of support members 23 to cover the active area A and the substrate structure 22, 32, wherein the antenna structure 2b includes a first antenna body 24a corresponding to the first antenna portion 200 and a second antenna body 24b, 34b corresponding to the second antenna portion 220, 320.

In an embodiment, a first air gap t1 is formed between the antenna structure 2b and the carrier structure 20. For example, a signal frequency between the first antenna body 24a and the first antenna portion 200 is corresponding to a height h1 of the first air gap t1. Alternatively, the first air gap t1 is located between the first antenna portion 200 and the first antenna body 24a. Alternatively, a second air gap t2, t3 is formed between the antenna structure 2b and the substrate structure 22, 32, and a height h2, h3 of the second air gap t2, t3 is less than the height h1 of the first air gap t1, so that a signal frequency between the second antenna body 24b and the second antenna portion 220, 320 is greater than the signal frequency between the first antenna body 24a and the first antenna portion 200.

In an embodiment, a second air gap t2, t3 is formed between the antenna structure 2b and the substrate structure 22, 32. For example, a signal frequency between the second antenna body 24b and the second antenna portion 220, 320 is corresponding to a height h2, h3 of the second air gap t2, t3. Alternatively, the second air gap t2, t3 is located between the second antenna portion 220, 320 and the second antenna body 24b, 34b.

In an embodiment, a plurality of the substrate structures 22, 32 are provided on the placement area B of the carrier structure 20. For example, a plurality of second air gaps t2, t3 are formed between the antenna structure 2b and the various substrate structures 22, 32. Furthermore, heights h2, h3 of the plurality of the second air gaps t2, t3 are different to one another, and the height h3 of the plurality of second air gaps t2, t3 is the smallest with a corresponding signal frequency between the second antenna body 24b and the second antenna portion 320 being the highest.

In an embodiment, the electronic package 2, 3, 4 further includes at least one electronic component 21, 41 disposed on the carrier structure 20.

In summary of the above, in the electronic package of the present disclosure and the method of manufacturing the same, substrate structures creating different radio frequencies can be provided on a single carrier structure, such that during mass production, antenna structures can be simply stacked on the carrier structures to produce RF products for various frequencies without the need to separately manufacture RF chips of each frequency into independent packages. Therefore, the electronic package of the present disclosure is capable of providing the electrical functions required for running a 5G system, thus meeting the requirements for antenna operations at various frequencies in the 5G system.

The above embodiments are set forth to illustrate the principles of the present disclosure, and should not be interpreted as to limit the present disclosure in any way. The above embodiments can be modified by one of ordinary skill in the art without departing from the scope of the present disclosure as defined in the appended claims.

What is claimed is:

1. An electronic package, comprising:
a carrier structure including a first antenna portion;
at least one substrate structure disposed on the carrier structure and including a second antenna portion; and
an antenna structure stacked on the carrier structure via a plurality of support members to cover the first antenna portion and the second antenna portion, wherein the antenna structure includes a first antenna body corresponding to the first antenna portion and a second antenna body corresponding to the second antenna portion.

2. The electronic package of claim 1, further comprising a first air gap formed between the antenna structure and the carrier structure.

3. The electronic package of claim 2, wherein a signal frequency between the first antenna body and the first antenna portion corresponds to a height of the first air gap.

4. The electronic package of claim 2, wherein the first air gap is located between the first antenna portion and the first antenna body.

5. The electronic package of claim 2, further comprising a second air gap formed between the antenna structure and the substrate structure, wherein a height of the second air gap is less than a height of the first air gap.

6. The electronic package of claim 5, wherein a signal frequency between the second antenna body and the second antenna portion is greater than a signal frequency between the first antenna body and the first antenna portion.

7. The electronic package of claim 1, further comprising an air gap formed between the antenna structure and the substrate structure.

8. The electronic package of claim 7, wherein a signal frequency between the second antenna body and the second antenna portion corresponds to a height of the air gap.

9. The electronic package of claim 7, wherein the air gap is located between the second antenna portion and the second antenna body.

10. The electronic package of claim 1, wherein a plurality of the substrate structures are disposed on the carrier structure.

11. The electronic package of claim 10, further comprising a plurality of air gaps formed between the antenna structure and each of the substrate structures.

12. The electronic package of claim 11, wherein heights of the plurality of air gaps are different from one another.

13. The electronic package of claim 12, wherein one of the plurality of air gaps with the smallest height has a corresponding signal frequency between the second antenna body and the second antenna portion that is the highest.

14. The electronic package of claim 1, further comprising an electronic component arranged on the carrier structure.

15. A method for manufacturing an electronic package, comprising:
providing at least one substrate structure including a second antenna portion on a carrier structure including a first antenna portion; and
stacking an antenna structure on the carrier structure via a plurality of support members to cover the first antenna portion and the second antenna portion, wherein the antenna structure includes a first antenna body corresponding to the first antenna portion and a second antenna body corresponding to the second antenna portion.

16. The method of claim 15, further comprising forming a first air gap between the antenna structure and the carrier structure.

17. The method of claim 16, wherein a signal frequency between the first antenna body and the first antenna portion corresponds to a height of the first air gap.

18. The method of claim 16, wherein the first air gap is located between the first antenna portion and the first antenna body.

19. The method of claim 16, further comprising forming a second air gap between the antenna structure and the substrate structure, wherein a height of the second air gap is less than a height of the first air gap.

20. The method of claim 19, wherein a signal frequency between the second antenna body and the second antenna portion is greater than a signal frequency between the first antenna body and the first antenna portion.

21. The method of claim 15, further comprising forming an air gap between the antenna structure and the substrate structure.

22. The method of claim 21, wherein a signal frequency between the second antenna body and the second antenna portion corresponds to a height of the air gap.

23. The method of claim 21, wherein the air gap is located between the second antenna portion and the second antenna body.

24. The method of claim 15, wherein a plurality of the substrate structures are disposed on the carrier structure.

25. The method of claim 24, further comprising forming a plurality of air gaps between the antenna structure and each of the substrate structures.

26. The method of claim 25, wherein heights of the plurality of air gaps are different from one another.

27. The method of claim 26, wherein one of the plurality of air gaps with the smallest height has a corresponding signal frequency between the second antenna body and the second antenna portion that is the highest.

28. The method of claim 15, further comprising arranging an electronic component on the carrier structure.
